(19) United States
(12) Patent Application Publication
(10) Pub. No.: US 2025/0176322 A1
(43) Pub. Date: May 29, 2025

(54) LIGHT EMITTING DEVICE, METHOD FOR MANUFACTURING LIGHT EMITTING DEVICE, AND IMAGE DISPLAY APPARATUS

(71) Applicant: SONY SEMICONDUCTOR SOLUTIONS CORPORATION, Kanagawa (JP)

(72) Inventor: Toshihiro MIURA, Kanagawa (JP)

(73) Assignee: SONY SEMICONDUCTOR SOLUTIONS CORPORATION, Kanagawa (JP)

(21) Appl. No.: 18/843,815

(22) PCT Filed: Mar. 6, 2023
(86) PCT No.: PCT/JP2023/008259

§ 371 Date: Sep. 4, 2024

(30) Foreign Application Priority Data
Mar. 14, 2022 (JP) 2022-039651

(51) Int. Cl. H10H 20/841; H10H 20/01; H10H 20/825; H10H 20/851

(52) U.S. Cl. CPC H10H 20/841; H10H 20/01335; H10H 20/034; H10H 20/0361; H10H 20/825; H10H 20/8514

(57) ABSTRACT

A light emitting device according to one embodiment of the present disclosure includes a light emitting element having a first surface as a light emitting surface and a second surface opposite to the first surface, a wavelength conversion layer that is provided on the first surface side and converts wavelength of light emitted from the light emitting element, and a reflection film collectively formed from at least a part of the second surface of the light emitting element to a side surface of the light emitting element and to a side surface of the wavelength conversion layer.

### TECHNICAL FIELD

The present disclosure relates to a light emitting device, a method for manufacturing thereof, and an image display apparatus.

### BACKGROUND ART

Patent Literature 1 discloses, as an example, a display apparatus provided with partition walls, each of which side surface having a reflection film, between a blue conversion layer, a green conversion layer, and a red conversion layer, provided on a light emitting layer.

CITATION LIST

### Patent Literature

Patent Literature 1: Japanese Unexamined Patent Application Publication No. JP 2020-086461

### SUMMARY OF THE INVENTION

It is to be noted that, there has been a demand that an image display apparatus, using light emitting diode (LED) as a light source of a display pixel, should improve luminance.

It is thus desirable to provide a light emitting device, a method for manufacturing a light emitting device, and an image display apparatus, which make it possible to improve luminance.

A light emitting device according to one embodiment of the present disclosure is provided with, a light emitting element having a first surface as a light emitting surface and a second surface opposite to the first surface, a wavelength conversion layer that is provided on the first surface side and converts wavelength of light emitted from the light emitting element, and a reflection film collectively formed from at least a part of the second surface of the light emitting element to a side surface of the light emitting element and to a side surface of the wavelength conversion layer.

A method for manufacturing a light emitting device according to one embodiment of the present disclosure includes: forming a separation groove that separates a GaN-based semiconductor layer provided on one surface of a silicon substrate and including a second conductive-type layer, an active layer, and a first conductive-type layer having a different conductive type from the second conductive-type layer stacked in this order, as a plurality of light emitting elements, from the first conductive-type layer side to a part of the silicon substrate; forming a reflection film continuously provided from surfaces of the plurality of light emitting elements, to a side surface and a bottom surface of the separation groove; and peeling off the silicon substrate from a surface opposite to the one surface, to form a plurality of openings sectioned by the separation groove for the respective plurality of light emitting elements, and thereafter forming a wavelength conversion layer in each of the plurality of openings.

An image display apparatus according to one embodiment of the present disclosure is provided with a light emitting device, and includes a light emitting device of one embodiment of the present disclosure as the light emitting device.

According to the light emitting device of one embodiment, the method for manufacturing the light emitting device of one embodiment, and the image display apparatus of one embodiment, of the present disclosure, a GaN-based semiconductor layer, making up a light emitting element and formed on a silicon substrate, is separated from a surface opposite to the silicon substrate side (a second surface opposite to a light emitting surface (a first surface)), to a part of the silicon substrate, and a reflection film is formed that extends continuously from a surface side opposite to a light emitting surface (a second surface) of the light emitting element, to a side surface of the light emitting element, as well as to a side surface of a wavelength conversion layer disposed on the light emitting surface side of the light emitting element. This makes it possible to suppress cross-talk between the adjacent light emitting elements, and also to improve light extraction efficiency.

### BRIEF DESCRIPTION OF DRAWING

FIG. 1 is a cross-sectional diagram illustrating a configuration of a light emitting device according to one embodiment of the present disclosure.

FIG. 2 is a schematic diagram illustrating one example of overall planar configuration of the light emitting device as illustrated in FIG. 1.

FIG. 3 is a schematic diagram illustrating a partially expanded planar configuration of the light emitting device as illustrated in FIG. 2.

FIG. 4 is a planar diagram illustrating one example of structure of a rear surface side of a light emitting element as illustrated in FIG. 1.

FIG. 5A is a cross-sectional diagram describing one example of manufacturing process of the light emitting device as illustrated in FIG. 1.

FIG. 5B is a cross-sectional diagram illustrating a process subsequent to FIG. 5A.

FIG. 5C is a cross-sectional diagram illustrating a process subsequent to FIG. 5B.

FIG. 5D is a cross-sectional diagram illustrating a process subsequent to FIG. 5C.

FIG. 5E is a cross-sectional diagram illustrating a process subsequent to FIG. 5D.

FIG. 5F is a cross-sectional diagram illustrating a process subsequent to FIG. 5E.

FIG. 5G is a cross-sectional diagram illustrating a process subsequent to FIG. 5F.

FIG. 5H is a cross-sectional diagram illustrating a process subsequent to FIG. 5H.

FIG. 5I is a cross-sectional diagram illustrating a process subsequent to FIG. 5H.

FIG. 5J is a cross-sectional diagram illustrating a process subsequent to FIG. 5I.

FIG. 5K is a cross-sectional diagram illustrating a process subsequent to FIG. 5J.

FIG. 6 is a cross-sectional diagram illustrating a configuration of a light emitting device according to a modification example 1 of the present disclosure.

FIG. 7 is a planar diagram illustrating one example of structure of a rear surface side of a light emitting element as illustrated in FIG. 6.

FIG. 8 is a planar diagram illustrating another example of structure of the rear surface side of the light emitting element as illustrated in FIG. 6.

FIG. 9 is a cross-sectional diagram illustrating a configuration of a light emitting device according to a modification example 2 of the present disclosure.

FIG. 10 is a cross-sectional diagram illustrating a configuration of a light emitting device according to a modification example 3 of the present disclosure.

FIG. 11 is a perspective diagram illustrating one example of configuration of an image display apparatus according to an application example of the present disclosure.

FIG. 12 is a schematic diagram illustrating one example of wiring layout of the image display apparatus as illustrated in FIG. 11.

FIG. 13 is a perspective diagram illustrating one example of configuration of an image display apparatus according to an application example of the present disclosure.

FIG. 14 is a perspective diagram illustrating a configuration of a mounting substrate as illustrated in FIG. 13.

FIG. 15 is a perspective diagram illustrating a configuration of a unit substrate as illustrated in FIG. 13.

FIG. 16 is a diagram illustrating an example of an image display apparatus according to an application example of the present disclosure.

### MODES FOR CARRYING OUT THE INVENTION

In the following, one embodiment of the present disclosure will be described in detail with reference to the drawings. It is to be noted that the embodiment described below is a specific example of the present disclosure, and the present disclosure is not limited to the following embodiment. In addition, the arrangement, dimensions, dimension ratios, etc., of components in the present disclosure are not limited to the embodiment illustrated in each drawing. It is to be noted that the description will be given in the following order.
1. Embodiment (an example of light emitting device provided with a reflection film continuously provided on a light emitting element and a side surface of a wavelength conversion layer)
   1-1. Configuration of Light emitting device
   1-2. Method for Manufacturing Light emitting device
   1-3. Functions and Effects
2. Modification Examples
   2-1. Modification Example 1 (another example of light emitting device)
   2-2. Modification Example 2 (another example of light emitting device)
   2-3. Modification Example 3 (another example of light emitting device)
3. Application Examples

### 1. Embodiment

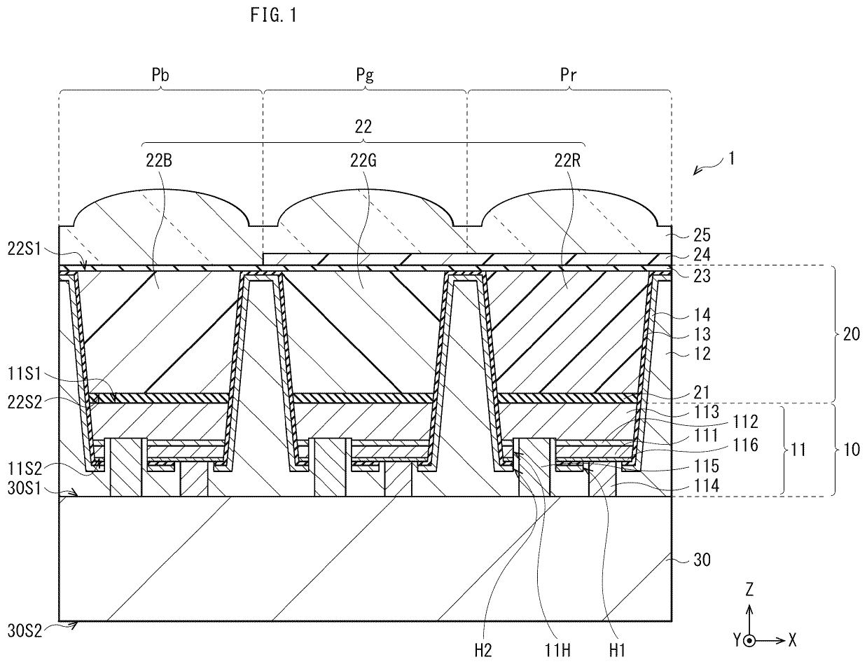

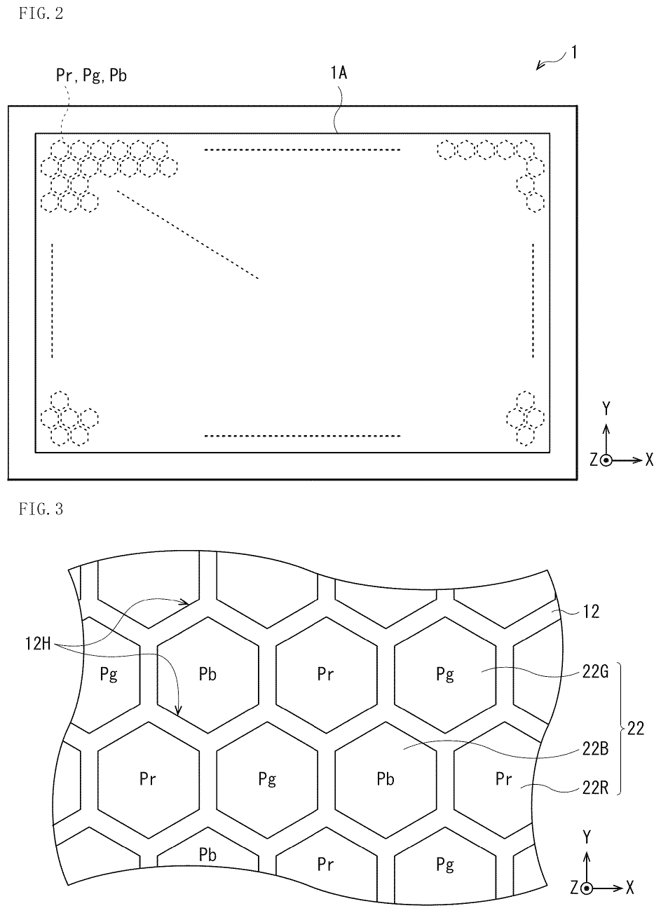

FIG. 1 is a cross-sectional diagram illustrating a configuration of a light emitting device (light emitting device 1) according to one embodiment of the present disclosure. FIG. 2 is a schematic diagram illustrating one example of overall planar configuration of the light emitting device 1 as illustrated in FIG. 1. The light emitting device 1 is suitably applicable, with regard to an image display apparatus commonly referred to as an LED display (for example, an image display apparatus 100, see FIG. 11), to a display (display region 100A).

### 1-1. Configuration of Light emitting Device

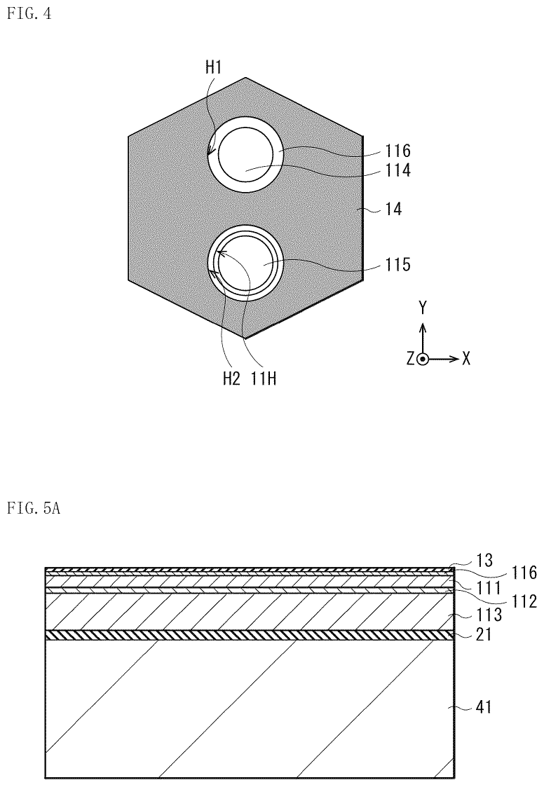

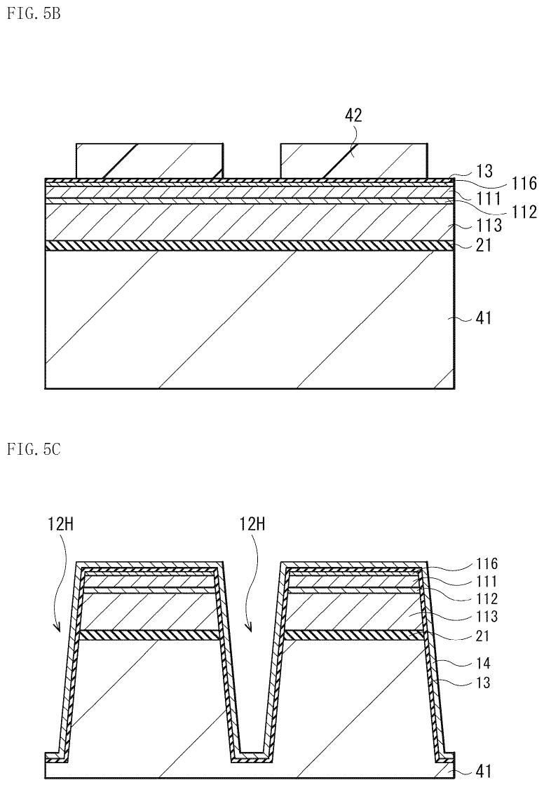

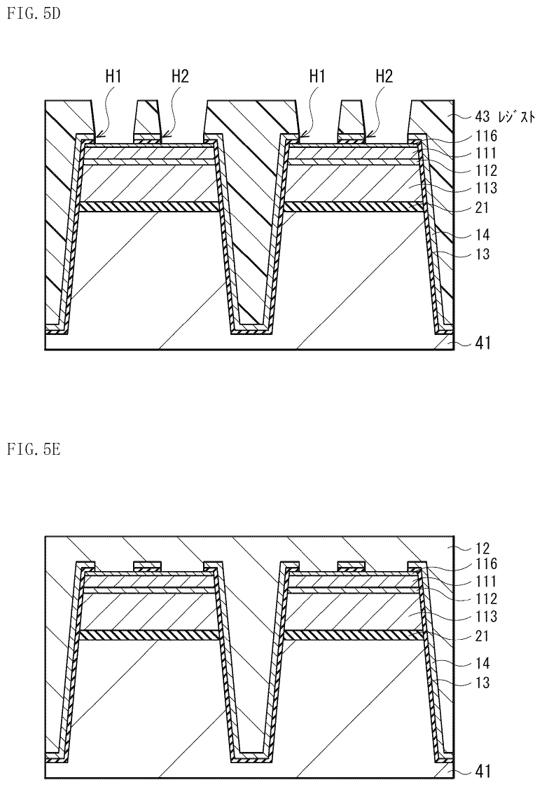

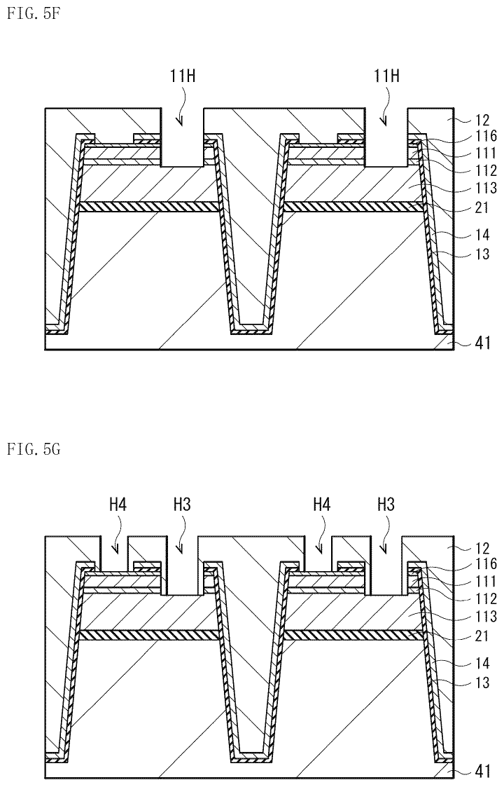

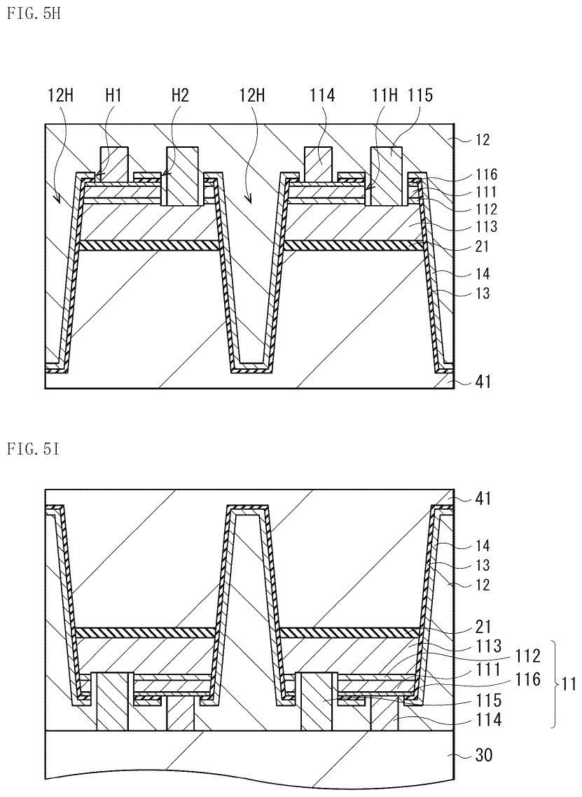

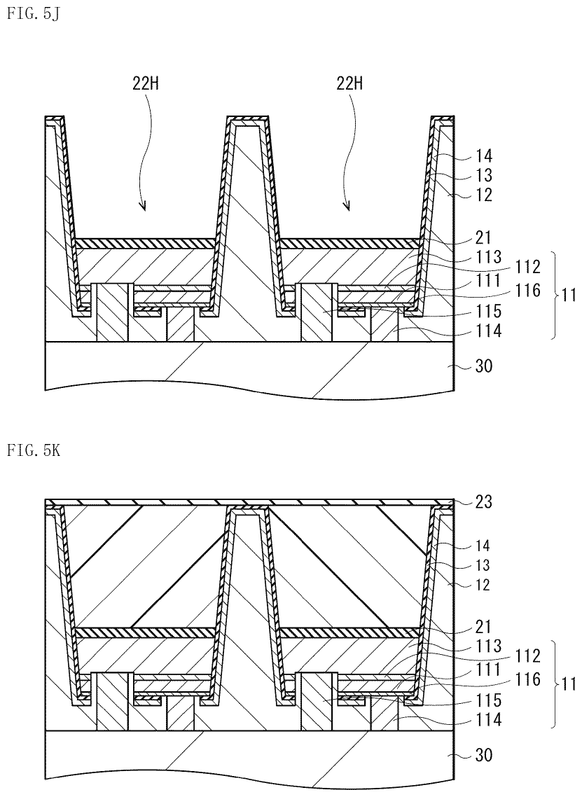

The light emitting device 1 includes, for example, a light emitter 10 including a plurality of light emitting elements 11 arranged in an array, and a wavelength converter 20 including a plurality of wavelength conversion layers respectively provided on each of the plurality of light emitting elements 11, stacked in this order on a circuit substrate 30, having a front surface (a surface 30S1) and a rear surface (a surface 30S2) opposing from each other, on the surface 30S1 side. The plurality of light emitting element 11 adjacent to each other and a plurality of wavelength conversion layers 22, respectively provided on the plurality of light emitting element 11, are separated from each other by a partition wall 12. With reference to the light emitting device 1 according to the embodiment of the present disclosure, a separation groove 12H for forming the partition wall 12 (see FIG. 5C) is collectively formed from a rear surface side (a surface 11S2) of the light emitting element 11, and an insulation film 13 and a reflection film 14 are collectively formed from the rear surface side (the surface 11S2) of the light emitting element 11 onto the separation groove 12H (see FIG. 5J), and thereafter, the partition wall 12 is formed by forming an oxide film, for example. As is clear from the above, with reference to the light emitting device 1 according to the embodiment of the present disclosure, the reflection film 14, covering the surface of the partition wall 12, is continuously formed, from at least a part of the rear surface of the light emitting element 11, to a side surface of the light emitting element 11 and to a side surface of the wavelength conversion layer 22.

The light emitter 10 includes, for example, the plurality of light emitting elements 11 arranged in the array on the surface 30S1 of the circuit substrate 30.

The light emitting element 11 corresponds to one specific example of “light emitting element” of the present disclosure. The light emitting element 11 is a solid-state light emitting element emitting light at a predetermined wavelength bandwidth from a light emitting surface (a surface 11S1), and is an LED (light emitting diode) chip, for example. The LED chip refers to that in a cut-out state from a wafer used for crystal growth, and does not refer to a package-type that is covered by formed resin, etc. The size of the LED chip is not less than 5 μm and not more than 100 μm, for example, which is commonly referred to as a micro LED.

The light emitting element 11 includes, for example, a first conductive-type layer 111, an active layer 112, and a second conductive-type layer 113, stacked in this order from the surface 30S1 side of the circuit substrate 30. With reference to the light emitting element 11, an upper surface of the second conductive-type layer 113 will be referred to as a light extraction surface (the surface 11S1), and a lower surface of the first conductive-type layer 111 will be referred to as the rear surface (the surface 11S2). The light emitting element 11 further includes, a p-electrode 114 for applying voltage to the first conductive-type layer 111, and an n-electrode 115 for applying voltage to the second conductive-type layer 113. The first conductive-type layer 111 corresponds to one specific example of a “first conductive-type layer” of the present disclosure, the active layer 112 corresponds to one specific example of an “active layer” of the present disclosure, and the second conductive-type layer 113 corresponds to one specific example of a “second conductive-type layer” of the present disclosure. The p-electrode 114 corresponds to one specific example of a “first electrode” of the present disclosure, and the n-electrode 115 corresponds to a “second electrode” of the present disclosure.

The first conductive-type layer 111 is formed by a p-type, GaN-based semiconductor material, for example. The active layer 112 has a multiplex quantum well structure, in which InGaN and GaN are stacked alternately, for example, and includes a light emitting region within the layer. Light in a blue bandwidth (blue light) at not less than 430 nm and not more than 500 nm, for example, is extracted from the active layer 112. Apart from this, it is also possible that, for example, light in a bandwidth corresponding to ultraviolet region (ultraviolet light) be extracted from the active layer 112. The second conductive-type layer 113 is formed by an n-type, GaN-based semiconductor material, for example.

The p-electrode 114 and the n-electrode 115 are electrically coupled, respectively, per the light emitting element 11, from the surface 11S2 side of the light emitting element 11, to the first conductive-type layer 111 and to the second conductive-type layer 113. Specifically, the p-electrode 114 is electrically coupled, from the surface 11S2 side to the first conductive-type layer 111, via a contact layer 116 provided on a lower surface of the first conductive-type layer 111. The n-electrode 115 is electrically coupled to the second conductive-type layer 113, via a recess 11H, which is provided from the surface 11S2 side of the light emitting element 11 (the lower surface of the first-conductive type layer 111) and reaching the second conductive-type layer 113. The p-electrode 114 and the n-electrode 115 are each electrically coupled to the circuit substrate 30.

The p-electrode 114 serves for applying voltage to the first conductive-type layer 111, and is electrically coupled to the first conductive-type layer 111 via the contact layer 116. The p-electrode 114 is a metal electrode, for example, and is formed as a multilayer body, such as titanium (Ti)/platinum (Pt)/gold (Au), or gold-germanium alloy (AuGe)/Ni (nickel)/Au, etc. Apart from that, it is also possible that the p-electrode 114 be formed by including highly-reflective metal material, such as silver (Ag), or aluminum (Al), etc.

The n-electrode 115 serves for applying voltage to the second conductive-type layer 113, and is electrically coupled to the second conductive-type layer 113. The n-electrode 115 is a metal electrode, for example, and is formed as a multilayer body, such as titanium (Ti)/platinum (Pt)/gold (Au), or gold-germanium alloy (AuGe)/Ni (nickel)/Au, etc. Apart from that, it is also possible that the n-electrode 115 be formed by including highly-reflective metal material, such as silver (Ag) or aluminum (Al), etc.

The contact layer 116 is provided on the lower surface of the first conductive-type layer 111, and is electrically coupled to the first conductive-type layer 111. This means that, the contact layer 116 is in ohmic contact with the first conductive-type layer 111. The contact layer 116 is formed by using, for example, a multilayer film (Ni/Au) of nickel (Ni) and gold (Au), or a transparent conductive material, such as indium-tin oxide (ITO), etc.

The partition wall 12 serves for suppressing occurrence of color mixture caused by leakage of light between the adjacent RGB subpixels (a red pixel Pr, a green pixel Pg, and a blue pixel Pb), in a case of applying the light emitting device 1 to the image display apparatus 100. The partition wall 12 has, for example, a honeycomb structure. Specifically, as illustrated in FIG. 3, the partition wall 12 has openings (separation grooves 12H), each of which is substantially in a regular hexagonal shape, for example, provided for the respective plurality of light emitting elements 11 arranged in the array. The partition wall 12 has an inclined surface as seen by a cross-sectional view, which, for example, causes a distance between the adjacent RGB subpixels to narrow gradually, from the surface 11S2 side of the light emitting element 11, toward a light extraction surface (21S1) of the wavelength conversion layer 22. In another expression, the partition wall 12 has, as seen by the cross-sectional view, a forward tapered shape between the adjacent color pixels Pr, Pg, and Pb. The partition wall 12 is formed, for example, by silicon oxide (SiO₂), or silicon nitride (Si₃N₄), etc.

The insulation film 13 serves for electrically insulating the reflection film 14, from the first conductive-type layer 111, the active layer 112, and the second conductive-type layer 113. Moreover, the insulation film 13 also serves for protecting the reflection film 14, when an Si substrate 41, which will be described later, is removed. The insulation film 13 has been continuously formed, from the surface 11S2 of the light emitting element 11, to the side surface of the light emitting element 11 and the side surface of the wavelength conversion layer 22. It is preferable that the insulation film 13 be formed by a material transparent to light emitted from the active layer 112. As an example of such material, it is possible to use silicon oxide (SiO₂), silicon nitride (Si₃N₄), aluminum oxide (Al₂O₃), titanium oxide (TiO₂), and titanium nitride (TiN), etc. As another example, it is also possible to use an organic material. The thickness of the insulation film 13 is, for example, in a range about 50 nm to 1 μm.

The reflection film 14 serves for reflecting light emitted from the active layer 112. The reflection film 14 has been continuously formed, with the insulation film 13 in between, from the surface 11S2 of the light emitting element 11, to the side surface of the light emitting element 11 and the side surface of the wavelength conversion layer 22. Furthermore, the reflection film 14 is provided to extend throughout an entire surface of an array 1A, in which the plurality of light emitting elements 11 is arranged in the array, for example. It is preferable that the reflection film 14 be formed by a material that reflects light emitted from the active layer 112. As an example of such material, it is possible to use titanium (Ti), aluminum (Al), silver (Ag), copper (Cu), gold (Au), nickel (Ni), and platinum (Pt), as well as an alloy thereof. As another example, it is also possible to use a dielectric multilayer material for the reflection film 14. The thickness of the reflection film 14 is, for example, in a range about 50 nm to 1 μm.

As illustrated in FIG. 4, the insulation film 13 and the reflection film 14 each has two openings H1, H2, in the surface 11S2 of the light emitting element 11. The opening H1 is provided above the contact layer 116, and the p-electrode 114, which is internally provided in the opening H1, is electrically coupled to the first conductive-type layer 111 via the contact layer 16 internally exposed in the opening H1. The opening H2 is provided to surround the recess 11H, which causes the second conductive-type layer 113 to be exposed on the surface 11S2 side, and the n-electrode 115, which is internally provided in the opening H2 and in the recess 11H, is electrically coupled to the second conductive-type layer 113 internally exposed in the recess 11H. The partition walls 12 are embedded, in a space between the p-electrode 114 and the opening H1, and in a space between the n-electrode 115 and the opening H2 as well as the recess 11H, respectively, thereby these spaces are electrically insulated.

The wavelength converter 20 is provided on a surface 10S1 side of the light emitter 10. As described above, the wavelength converter 20 includes the plurality of wavelength conversion layers 22, each of which is provided on the plurality of light emitting elements 11, respectively. The wavelength conversion layer 22 includes, a light extraction surface (a surface 22S1), which extracts light entering from the light emitting element 11 side and converted into a predetermined wavelength, and a rear surface (a surface 22S2), disposed on a side opposite to the surface 22S1, and opposing to the surface 11S1 of the light emitting element 11. The wavelength converter 20 includes protection layers 21, 23, respectively disposed on the surface 22S2 side and on the surface 22S1 side of the wavelength conversion layer 22.

The protection layer 21 serves for protecting the surface 11S1 of the light emitting element 11, for example. The protection layers 21 are each provided on the plurality of light emitting elements 11 arranged in the array. The protection layer 21 is formed, for example, by silicon oxide (SiO₂), or silicon nitride (Si₃N₄).

The wavelength conversion layer 22 corresponds to one specific example of a “wavelength conversion layer” of the present disclosure. The wavelength conversion layers 22 are each provided on the surface 11S1 side of each of the light emitting element 11, and each serves for converting light, which has been emitted from each of the plurality of light emitting elements 11, into a desired wavelength (for example, red ®/green (G)/blue (B)), and also serves for emitting the converted light. Specifically, the red pixel Pr is provided with a red wavelength conversion layer 22R for converting light, emitted from the light emitting element 11, into red bandwidth light (red light), the green pixel Pg is provided with a green wavelength conversion layer 22G for converting light, emitted from the light emitting element 11, into green bandwidth light (green light), and the blue pixel Pb is provided with a blue wavelength conversion layer 22B for converting light, emitted from the light emitting element 11, into blue bandwidth light (blue light), respectively.

It is possible to form the wavelength conversion layers 22R, 22G, 22B, by using a quantum dot, for example, corresponding to the respective colors. Specifically, in a case of acquiring red light, it is possible to select a quantum dot, for example, from InP, GaInP, InAsP, CdSe, CdZnSe, CdTeSe, or CdTe, etc. In a case of acquiring green light, it is possible to select a quantum dot, for example, from InP, GaInP, ZnSeTe, ZnTe, CdSe, CdZnSe, CdS, or CdSeS, etc. In a case of acquiring blue light, it is possible to select a quantum dot, for example, from ZnSe, ZnTe, ZnSeTe, CdSe, CdZnSe, CdS, CdZnS, or CdSeS, etc. Note that, in a case that blue light is emitted from the light emitting element 11 as described above, it is also possible to form the blue wavelength conversion layer 22B by using a resin layer having a light transmission property.

The protection layer 23 serves for protecting the surface 22S1 of the wavelength conversion layer 22. The protection layer 23 is provided to extend throughout the entire surface of the light emitter 10 in which the plurality of light emitting elements 11 is arranged in the array. The protection layer 23 is formed, for example, by silicon oxide (SiO₂), or silicon nitride (Si₃N₄).

Furthermore, in a case that blue light is emitted from the light emitting element 11, it is also possible to provide a wavelength selection layer 24, which selectively reflects blue light, for example, on the protection layers 23 of the red pixel Pr and the green pixel Pg. This makes it possible to reduce blue light emitted from the surface 22S1 of the wavelength conversion layer 22, which contributes to improvement of color gamut. Moreover, it is possible to improve contrast of external light. Note that, it is also possible to dispose a yellow filter, which selectively absorbs blue light, in place of the wavelength selection layer 24.

Moreover, in a case that ultraviolet light is emitted from the light emitting element 11, a wavelength selection layer 24, which selectively reflects ultraviolet light, is provided throughout the entire surface of the red pixel Pr, the green pixel Pg, and the blue pixel Pb.

In addition, it is also possible to dispose an on-chip lens 25 on the surface 22S1 of the wavelength conversion layer 22. Moreover, other than the on-chip lens 25, it is also possible to provide a photonic crystal, a moth-eye structure, a nano-antenna, or a meta-material. This makes it possible to improve luminance on a low-angle side.

The circuit substrate 30 is provided with a drive circuit, etc., which controls driving of the plurality of light emitting elements 11 arranged in the array 1A. It is possible to provide a heat dissipation member, for example, on a surface (a surface 30S2), which is opposite to a surface (a surface 30S1) opposing to the light emitter 10 of the circuit substrate 30. The heat dissipation member is a metal plate such as Cu, etc., having high thermal conductivity. It is also possible to further provide a plurality of heat dissipation fins on the metal plate.

### 1-2. Method for Manufacturing Light Emitting Device

It is possible to manufacture the light emitting device 1 of the present disclosure, for example, by a method described below. FIG. 5A to FIG. 5K illustrate one example of manufacturing process of the light emitting device 1.

First, for example, a sapphire substrate is used as a growth substrate, and a semiconductor stack, including the first conductive-type layer 111, the active layer 112, and the second conductive-type layer 113, is formed on the sapphire substrate, by epitaxial crystal growth, using, for example, metal organic chemical vapor deposition (MOCVD), or molecular beam epitaxy (MBE), etc. Next, the semiconductor stack is separated into 10 mm-square chips, and as illustrated in FIG. 5A, and each chip is mounted on the silicon (Si) substrate 41, with an insulation film (for example, a silicon oxide film) interposing therebetween, serving as the protection layer 21. Furthermore, as illustrated in FIG. 5A, the contact layer 116 and the insulation film 13 are formed on the semiconductor stack (specifically, above the first conductive-type layer 111).

Subsequently, as illustrated in FIG. 5B, after a resist 42 is patterned on the insulation film 13, for example by photolithography and dry etching, etching is undergone until reaching a part of the Si substrate 41, thereby the separation grooves 12H are formed, which separate the insulation film 13, the contact layer 116, the first conductive-type layer 111, the active layer 112, and the second conductive-type layer 113.

Next, as illustrated in FIG. 5C, after forming the insulation film 13 on the insulation film 13 as well as on the side surface and a bottom surface of the separation groove 12H, for example by using atomic layer deposition (ALD), the reflection film 14 is continuously formed, from the surface 11S2 side of the light emitting element 11, to the side surface of the light emitting element 11 and to the side surface of the Si substrate 41, for example by using chemical vapor deposition (CVD).

According to the above method, the continuous reflection film 14, with no steep different level between the light emitting element 11 and the wavelength conversion layer 22, which will be formed in a process described later, is collectively formed on the side surface of the light emitting element 11 and on the side surface of the wavelength conversion layer 22.

Subsequently, as illustrated in FIG. 5D, after patterning a resist 43 on the surface 11S2 of the light emitting element 11 to fill the separation groove 12H, for example by photolithography and dry etching, the openings H1, H2, which cause the contact layer 116 to be exposed, are formed.

Next, after removing the resist 43, as illustrated in FIG. 5E, a silicon oxide film is formed, for example, thereby the partition wall 12, which fills the separation groove 12H and embeds the light emitting element 11 from the surface 11S2 side, is formed. Thereafter, the surface of the silicon oxide film forming the partition wall 12, is flattened by chemical mechanical polishing (CMP).

Next, as illustrated in FIG. 5F, for example by photolithography and dry etching, the recess 11H reaching the second conductive-type layer 113 is formed at a position of the opening H2, and thereafter, the recess 11H is filled by forming a silicon oxide film, for example. Thereafter, as illustrated in FIG. 5G, an opening H3, having a diameter smaller than those of the opening H2 and the recess 11H and reaching the second conductive-type layer 113, is formed by photolithography and dry etching, for example. Next, as illustrated in FIG. 5G, an opening H4, having a diameter smaller than that of the opening H1 and causing the contact layer 116 to be exposed, is formed at a position of the opening H1 by photolithography and dry etching, for example.

Subsequently, as illustrated in FIG. 5H, after filling the openings H3, H4 by forming metal films, the metal films formed on the partition wall 12, is removed by CMP, thereby the p-electrode 114 and the n-electrode 115 are formed. Thereafter, although not illustrated, pad electrodes are formed on the p-electrode 114 and the n-electrode 115, and a silicon oxide film forming the partition wall 12, is formed again.

Next, the surface of the silicon oxide film forming the partition wall 12, is flattened, and furthermore, the pad electrodes on the p-electrode 114 and on the n-electrode 115 are exposed, by CMP, and as illustrated in FIG. 5I, the p-electrode 114 and the n-electrode 115 are each coupled to the circuit substrate 30 by hybrid bonding.

Subsequently, as illustrated in FIG. 5J, the Si substrate 41 is removed by etching, for example, thereby an opening 22H is formed. Next, as illustrated in FIG. 5K, the wavelength conversion layer 22 is formed in the opening 22H, for example by coating method. Then, after forming the protection layer 23 on the partition wall 12 and the wavelength conversion layer 22, the wavelength selection layer 24 and the on-chip lens 25 are formed on the protection layer 23. According to the method as described above, the light emitting device 1 as illustrated in FIG. 1 is completed.

### 1-3. Functions and Effects

According to the light emitting device 1 of the present embodiment, a GaN-based semiconductor layer (the first conductive-type layer 111, the active layer 112, and the second conductive-type layer 113) making up the light emitting element 11 and formed on the Si substrate 41 is separated from the surface side opposite to the Si substrate 41 side (the surface 11S2 of the light emitting element 11) to a part of the Si substrate 41, and the reflection film 14 is collectively formed that extends continuously from the surface 11S2 side of the light emitting element 11 to the side surface of the light emitting element 11 as well as to the side surface of the wavelength conversion layer 22. This makes it possible to suppress cross-talk between the adjacent color pixels, and also to improve light extraction efficiency. These effects will be explained in detail below.

Recently, there is a popularization of high-definition image display apparatus, provided with light emitting devices using solid-state light emitting elements such as LEDs as a light source. This type of light emitting device includes, for example, a plurality of LEDs arranged in a two-dimensional array, and color converters are disposed above them. With regard to a typical light emitting device, the height of the LED is 2 μm to 4 μm, and the height of the color converter is 5 μm or more, and the color converters, provided on the respective LEDs, are separated from each other by a separation wall, which is referred to, for example, as a partition wall.

It is to be noted that an LED emits light omnidirectionally from an active layer. Because of this, with regard to a typical light emitting device, there is an issue of cross-talk, in which, light emitted in a diagonal direction leaks into an adjacent pixel, and causes a color converter of non-desired, another pixel, to emit light. For the purpose of solving this issue, it has been proposed that a reflection wall, which entirely separates the respective LEDs and the color converters, be provided.

The separation walls, which entirely separates the respective LEDs and the color converters, are formed by independent processes. Generally, after forming the LED and the separation wall thereof, the separation wall (partition wall) of the color converter is formed on the LED. The separation wall of the LED and the color converter, formed by the process described above, has a width wider than the separation wall of the LED, by considering any misalignment due to the independent forming processes. Consequently, light emitted from the LED partially rebounds at a bottom surface of the separation wall of a wavelength converter protruding from the separation wall of the LED. Moreover, amount of rebound of light at the bottom surface of the separation wall of the wavelength converter becomes irregular due to unevenness of dimension of the separation wall of the wavelength converter and misalignment against the LED. These issues become significant in a case that a pixel pitch becomes more refined.

On the other hand, according to the present embodiment, a GaN-based semiconductor layer (the first conductive-type layer 111, the active layer 112, and the second conductive-type layer 113) making up the light emitting element 11 and formed on the Si substrate 41 is separated from the surface side opposite to the Si substrate 41 side (the surface 11S2 of the light emitting element 11) to a part of the Si substrate 41, and the reflection film 14 is collectively formed that extends continuously from the surface 11S2 side of the light emitting element 11 to the side surface of the light emitting element 11 as well as to the side surface of the wavelength conversion layer 22. Accordingly, the light emitting elements 11 and the wavelength conversion layers 22 of the adjacent pixels are entirely separated, and the cross-talk between the adjacent pixels are reduced. Moreover, because the reflection film 14 is formed on the side surface of the light emitting element 11 and on the side surface of the wavelength conversion layer 22, which form a substantially continuous surface, the rebound of light at a lower part of the wavelength converter 20 as described above is reduced, which contributes to improvement of light extraction efficiency.

As described above, by applying the light emitting device 1 of the present embodiment to the image display apparatus, it is possible to improve luminance. In addition, it is also possible to improve color reproducibility.

Next, modification examples 1 to 3 and an application example of the present disclosure will be explained. Note that, the same reference signs will be assigned to any structural elements corresponding to those of the light emitting device 1 of the above embodiment, and the explanation thereof will be omitted.

### 2. Modification Examples

### 2-1. Modification Example 1

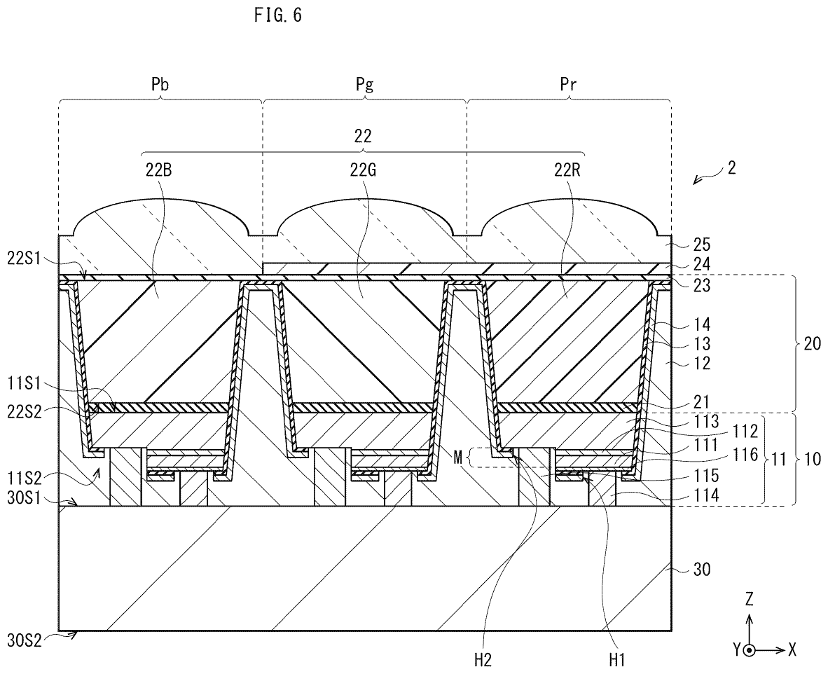

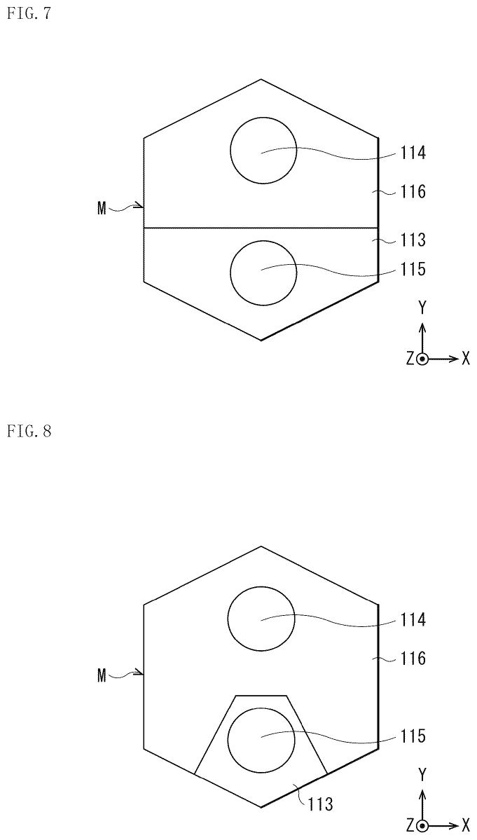

FIG. 6 is a diagram illustrating a cross-sectional configuration of a light emitting device (a light emitting device 2) according to a modification example 1 of the present disclosure. FIG. 7 is a diagram illustrating one example of structure of a rear surface side (the surface 11S2) of the light emitting element 11 as illustrated in FIG. 6. FIG. 8 is a diagram illustrating another example of structure of the rear surface side (the surface 11S2) of the light emitting element 11 as illustrated in FIG. 6. Similar to the above embodiment, the light emitting device 2 is suitably applicable to a display of an image display apparatus, commonly referred to as an LED display (for example, the image display apparatus 100). The light emitting device 2 of the present modification example is different from the above embodiment, in that the surface 11S2 of the light emitting element 11 has a columnar mesa structure, including the first conductive-type layer 111 and the active layer 112.

Because the recess 11H of the above embodiment expands to an external shape of the light emitting element 11, the light emitting element 11 of the present modification example includes a step, formed by a protrusion (a mesa M) including the first conductive-type layer 111 and the active layer 112, and also including the recess 11H from which the second conductive-type layer 113 is exposed. Note that, as illustrated in FIG. 7 and FIG. 8, the shape of the recess 11H forming the mesa M is not specifically limited.

It is possible to form the light emitting device 2 of the present modification example by a process that, before separating the insulation film 13, the contact layer 116, the first conductive-type layer 111, the active layer 112, and the second conductive-type layer 113, and after forming the recess 11H from which the second conductive-type layer 113 is exposed, the resist 42 (see FIG. 5B), covering the exposed second conductive-type layer 113, is patterned, and thereafter, the same process as that of the above embodiment is undergone.

As described above, with reference to the light emitting device 2 of the present modification example, the surface 11S2 side of the light emitting element 11 has the mesa structure. According to this modification example, it is also possible to achieve substantially the same effects as those of the above embodiment.

### 2-2. Modification Example 2

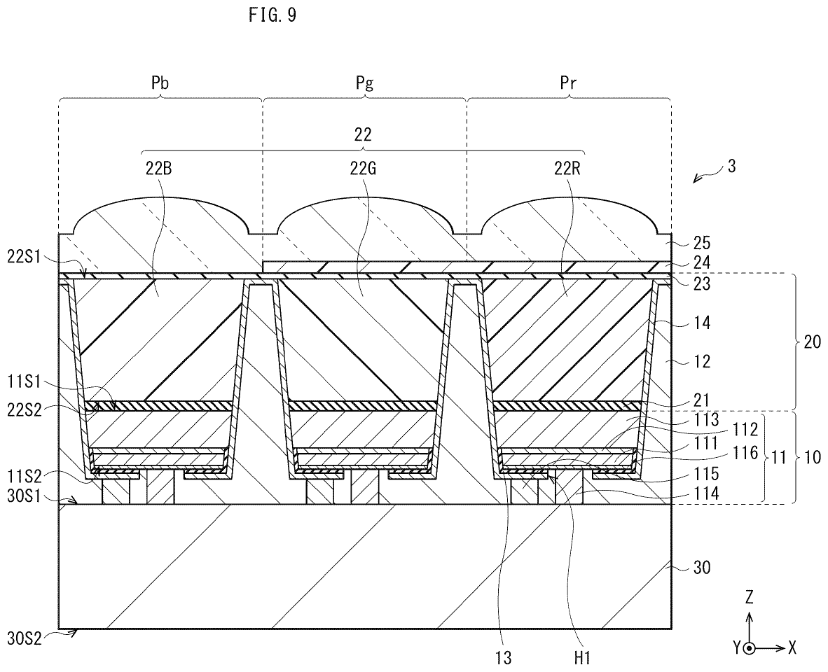

FIG. 9 is a diagram illustrating a cross-sectional configuration of a light emitting device (a light emitting device 3) according to a modification example 2 of the present disclosure. Similar to the above embodiment, the light emitting device 3 is suitably applicable to a display of an image display apparatus, commonly referred to as an LED display (for example, the image display apparatus 100). The light emitting device 3 of the present modification example is different from the above embodiment, in that the second conductive-type layer 113 is electrically coupled to the n-electrode 115 via the reflection film 14 on the side surface of the second conductive-type layer 113.

As described above, with reference to the light emitting device 3 of the present modification example, the recess 11H, from which the second conductive-type layer 113 is exposed, is not formed on the surface 11S2 side of the light emitting element 11, and instead, the side surface of the second conductive-type layer 113 is coupled to the reflection film 14, thereby voltage is applied from the side surface of the second conductive-type layer 113. According to this modification example, it is also possible to achieve substantially the same effects as those of the above embodiment.

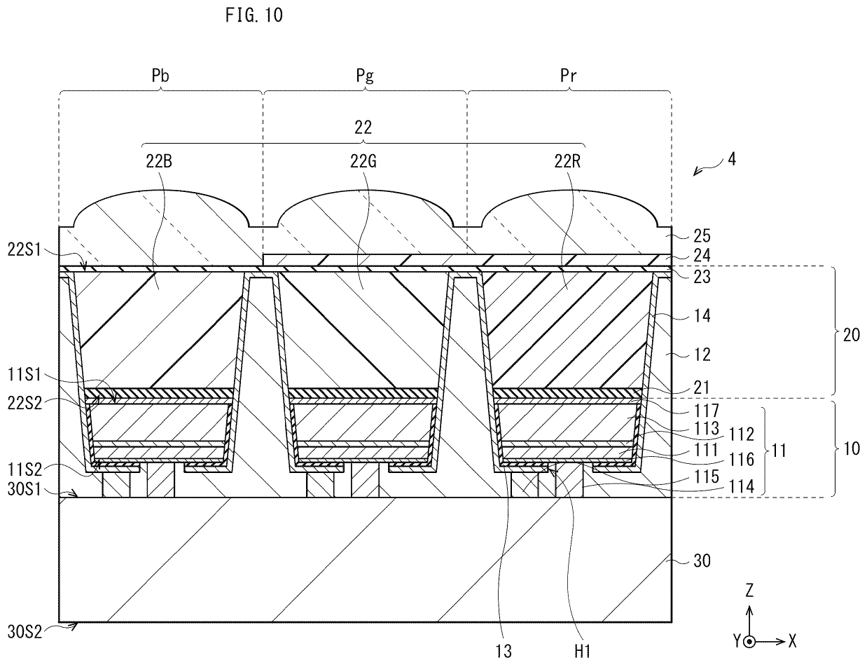

Note that, with reference to the present modification example, for the purpose of securing electric connection between the second conductive-type layer 113 and the reflection film 14, the insulation film 13 is formed, from the surface 11S2 side of the light emitting element 11, to the active layer 112, or to a part of the second conductive-type layer 113. In a case that erosion when removing the Si substrate 41 is minimal, it is possible to omit the reflection film 14 in a region of the wavelength conversion layer 22, as illustrated in FIG. 10.

### 2-3. Modification Example 3

FIG. 10 is a diagram illustrating a cross-sectional configuration of a light emitting device (a light emitting device 4) according to a modification example 3 of the present disclosure. Similar to the above embodiment, the light emitting device 4 is suitably applicable to a display of an image display apparatus, commonly referred to as an LED display (for example, the image display apparatus 100). The light emitting device 4 of the present modification example is different from the above embodiment, in that the second conductive-type layer 113 is electrically coupled to the n-electrode 115 via a contact layer 117 and the reflection film 14, provided on the second conductive-type layer 113.

The contact layer 117 is provided on an upper surface (the surface 11S1) of the second conductive-type layer 113, and is electrically coupled to the second conductive-type layer 113. This means that, the contact layer 117 is in ohmic contact with the second conductive-type layer 113. The contact layer 117 is formed, similar to the contact layer 116, by using, for example, a multilayer film (Ni/Au) of nickel (Ni) and gold (Au), or a transparent conductive material, such as indium-tin oxide (ITO), etc.

As described above, with reference to the light emitting device 3 of the present modification example, the contact layer 117 is provided on the upper surface (the surface 11S1) of the second conductive-type layer 113, and the second conductive-type layer 113 is electrically coupled to the n-electrode 115 via the contact layer 117 and the reflection film 14. Consequently, as compared with the light emitting device 3 of the above modification example 2, it is possible to improve the electric connection between the second conductive-type layer 113 and the n-electrode. This makes it possible to improve reliability.

### 3. Application Examples

### Application Example 1

FIG. 11 is a perspective diagram illustrating one example of overall configuration of an image display apparatus (the image display apparatus 100) according to an application example of the present disclosure. The image display apparatus 100 is commonly referred to as an LED display, for which the light emitting device of the present disclosure (for example, the light emitting device 1) is used as display pixels. As illustrated in FIG. 11, for example, the image display apparatus 100 is provided with a display panel 110, and a control circuit 140 for driving the display panel 110.

The display panel 110 is formed by overlaying a mounting substrate 120 and a counter substrate 130 with each other. A front surface of the counter substrate 130 serves as a picture display surface, and includes a display region (a display 110A) at a center thereof, and also includes a frame region 110B as a non-display region around the display region.

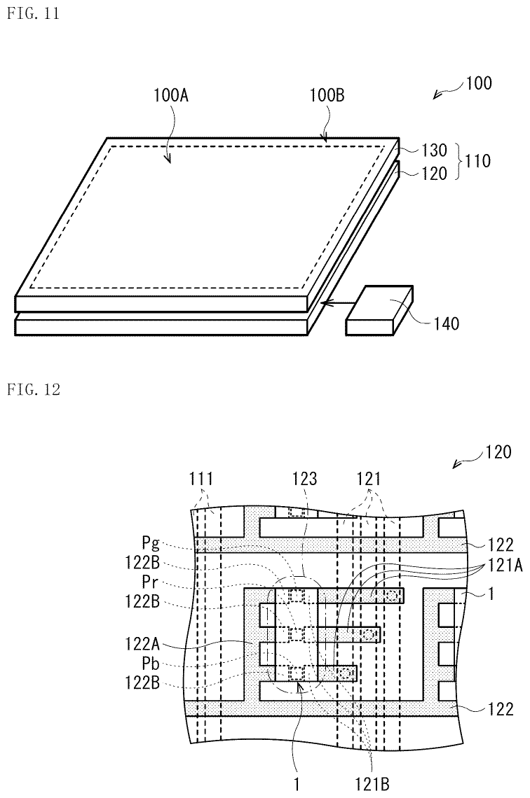

FIG. 12 is a schematic diagram illustrating one example of wiring layout of a region corresponding to the display 110A, with reference to the front surface of the counter substrate 130 of the mounting substrate 120. As illustrated in FIG. 12, for example, a plurality of data wirings 121 is formed to extend in a predetermined direction, and furthermore, is arranged in parallel at predetermined intervals, in the region corresponding to the display 110A with reference to the front surface of the mounting substrate 120. In addition, for example, a plurality of scan wirings 122 is formed to extend in a direction intersecting with (for example, orthogonal to) the data wirings 121, in the region corresponding to the display, in the region corresponding to the display 110A with reference to the front surface of the mounting substrate 120. The data wirings 121 and the scan wirings 122 include conductive material such as Cu, for example.

The scan wirings 122 are formed on an outermost surface, for example, and are formed on an insulation layer (not illustrated) formed on a front surface of base material, for example. Note that, the base material of the mounting substrate 120 includes silicon substrate or resin substrate, etc., for example, and the insulation layer on the base material includes SiN, SiO, aluminum oxide (AlO), or resin material, etc., for example. In contrast, the data wirings 121 are formed in an inside of a layer different from the outermost layer including the scan wirings 122 (for example, a layer lower than the outer most layer), and are formed, for example, in an inside of the insulation layer on the base material.

A display pixel 123 is formed in a region adjacent to the intersection of the data wirings 121 with the scan wirings 122, and the plurality of display pixels 123 is disposed in a matrix in an inside of the display 110A. The color pixels Pr, Pg, Pb of the light emitting device 1, for example, is respectively mounted on each of the display pixels 123.

The light emitting device 1 is provided with terminal electrodes, which are disposed as a pair, or as that one is disposed as a common terminal and another is disposed as a respective terminal of the color pixels Pr, Pg, Pb, for example. Moreover, one of the terminal electrodes is electrically coupled to the data wirings 121, and the other of the terminal electrodes is electrically coupled to the scan wirings 122. For example, one of the terminal electrodes is electrically coupled to a pad electrode 121B at a tip of a branch 121A provided in the data wirings 121. Moreover, for example, the other of the terminal electrodes is electrically coupled to a pad electrode 122B at a tip of a branch 122A provided in the scan wirings 122.

The pad electrodes 121B, 122B are each formed on the outermost layer, for example, and as illustrated in FIG. 12, for example, are each provided at a position on which each of the light emitting devices 1 is mounted. In the present example, the pad electrodes 121B, 122B include conductive material such as gold (Au), for example.

The mounting substrate 120 is further provided, for example, with a plurality of pillars (not illustrated) which regulate a space between the mounting substrate 120 and the counter substrate 130. It is possible to provide the pillars in a region opposing to the display 110A, and it is also possible to provide the pillars in a region opposing to the frame 110B.

The counter substrate 130 includes glass substrate or resin substrate, for example. With reference to the counter substrate 130, it is possible to form the front surface on the light emitting device 1 side as a flat surface, but it is preferable to form as a rough surface. It is possible to provide the rough surface throughout an entire region opposing to the display 110A, and it is also possible to provide the rough surface only in a region opposing to the display pixels 123. The rough surface has a fine unevenness, for entering light emitted from the color pixels Pr, Pg, Pb. It is possible to prepare unevenness of the rough surface, for example by sandblasting, dry etching, etc.

The control circuit 140 drives each of the display pixels 123 (each of the light emitting devices 1) based on picture signal. The control circuit 140 includes, for example, a data driver for driving the data wirings 121 coupled to the display pixels 123, and a scan driver for driving the scan wirings 122 coupled to the display pixels 123. It is possible to provide the control circuit 140, for example as illustrated in FIG. 11, as being separated from the display panel 110 and also coupled to the mounting substrate 120 via wirings, or as being mounted on the mounting substrate 120.

### Application Example 2

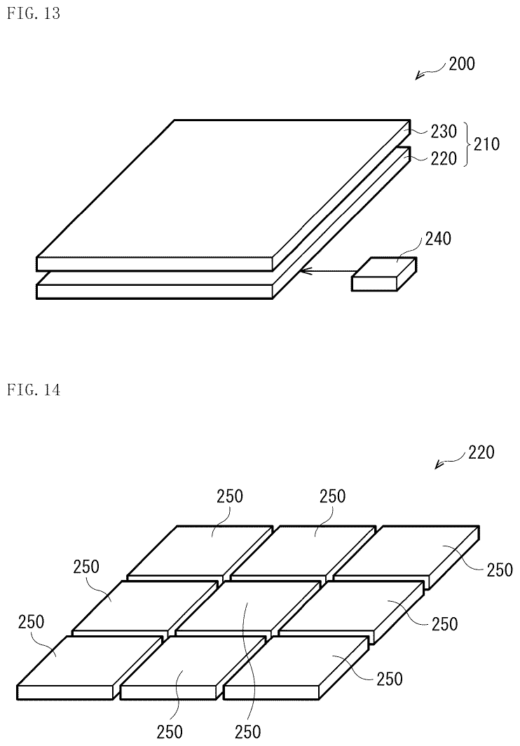

FIG. 13 is a perspective diagram illustrating another example of configuration of an image display apparatus (an image display apparatus 200) using a light emitting device (for example, the light emitting device 1) of the present disclosure. The image display apparatus 200 is commonly referred to as a tiling display, using a plurality of light emitting devices, in which LEDs are used as a light source. The image display apparatus 200 is provided, for example as illustrated in FIG. 13, with a display panel 210, and a control circuit 240 for driving the display panel 210.

The display panel 210 is formed by overlaying a mounting substrate 220 and a counter substrate 230 with each other. A front surface of the counter substrate 230 serves as a picture display surface, and includes a display region at a center thereof, and also includes a frame region as a non-display region around the display region (neither will be illustrated). The counter substrate 230 is disposed at a position opposing to the mounting substrate 220, with a predetermined gap, for example. Note that, it is also possible to provide the counter substrate 230 being in contact with an upper surface of the mounting substrate 220.

FIG. 14 is a perspective diagram illustrating one example of configuration of the mounting substrate 220. As illustrated in FIG. 14, for example, the mounting substrate 220 is formed by a plurality of unit substrates 250 laid in a form of tiles. Note that, although FIG. 14 illustrates an example in which the mounting substrate 220 is formed by nine unit substrates 250, the number of the unit substrates 250 may be ten or more, or eight or less.

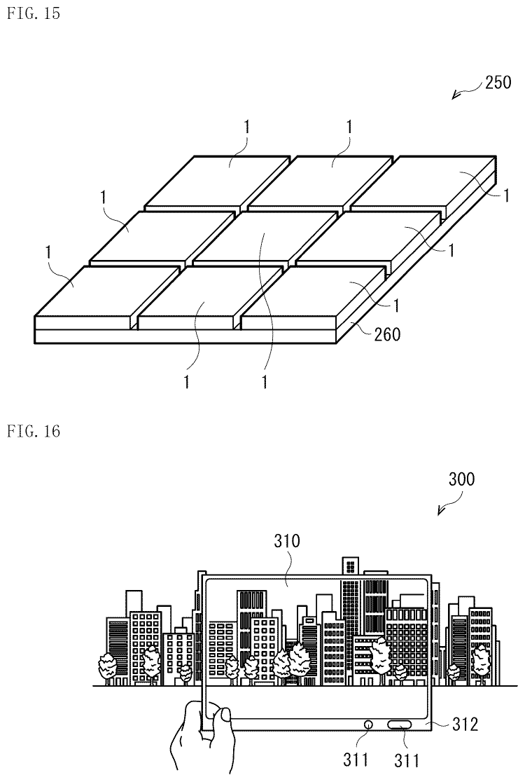

FIG. 15 illustrates one example of configuration of the unit substrate 250. The unit substrate 250 includes, for example, the plurality of light emitting device 1 laid in a form of tiles, and a support substrate 260 for supporting each of the light emitting devices 1. Each of the unit substrates 250 further includes a control substrate (not illustrated). The support substrate 260 is formed by a metal frame (metal plate) or a wiring substrate, for example. In a case that the support substrate 260 is formed by the wiring substrate, it is also possible to serve as the control substrate. In this case, the support substrate 260, the control substrate, or both, is electrically coupled to each of the light emitting device 1.

### Application Example 3

FIG. 16 illustrates an external appearance of a transparent display 300. The transparent display 300 includes, for example, a display 310, a controller 311, and a housing 312. The display 310 uses the light emitting device of the present disclosure (for example, the light emitting device 1). With reference to this transparent display 300, it is possible to indicate images and character information, while transmitting a background view beyond the display 310.

A mounting substrate of the transparent display 300 uses a substrate having a light transmission property. Similar to the mounting substrate, each of electrodes provided on the light emitting device 1 has been formed by using a conductive material having a light transmission property. As an alternative example, each of the electrodes has a structure hard to be visually recognized, by reducing a width of a wiring, or reducing a thickness the wiring. Moreover, the transparent display 300 allows black display, by overlaying liquid crystal layers each provided with a driving circuit, for example, and also allows switching between the transparent display and black display by controlling a light distribution direction of the liquid crystal.

The technology according to the present disclosure has been explained above, with reference to the embodiment, the modification examples 1 to 3, and the application examples, but the technology according to the present disclosure is not limited to the above-described embodiment and the like., and is modifiable in a variety of ways. For example, according to the present embodiment, as an example, the blue light or the ultraviolet light is disclosed as the light emitted from the light emitting element 11, but the light is not limited to these types. For example, the light emitting device 1 may also use a light emitting element, which emits two or more types of light, such as the blue light and the green light, or the ultraviolet light and the green light.

Moreover, according to the above embodiment or the like, each member forming the light emitting device 1, etc., has been explained by mentioning a specific member, but the complete members are not indispensable, and it is also possible to be provided with further members. For example, it is possible to omit the protection layer 21 between the light emitting element 11 and the wavelength conversion layer 22, and to stack the wavelength conversion layer 22 directly on the light emitting element 11.

Note that, the effects disclosed in the present Description are all described as a mere explanation purpose and not limited to these disclosures, and it is also possible to achieve other effects.

The technology according to the present disclosure may also have configurations described below. According to the technology of the present disclosure having the configurations described below, a GaN-based semiconductor layer, making up a light emitting element and formed on a silicon substrate, is separated from a surface opposite to the silicon substrate side (a second surface opposite to a light emitting surface (a first surface)), to a part of the silicon substrate, and a reflection film is formed that extends continuously from a surface side opposite to a light emitting surface (a second surface) of the light emitting element, to a side surface of the light emitting element, as well as to a side surface of a wavelength conversion layer disposed on the light emitting surface side of the light emitting element. This makes it possible to suppress cross-talk between the adjacent light emitting elements, and also to improve light extraction efficiency. Accordingly, it is possible to improve luminance.

(1)

A light emitting device including:
a light emitting element having a first surface as a light emitting surface and a second surface opposite to the first surface;
a wavelength conversion layer that is provided on the first surface side and converts wavelength of emitted light emitted from the light emitting element; and
a reflection film collectively formed from at least a part of the second surface of the light emitting element, to a side surface of the light emitting element and to a side surface of the wavelength conversion layer.
   (2)

The light emitting device according to (1), in which the wavelength conversion layer has a third surface from which the emitted light after wavelength conversion is extracted, and a fourth surface opposite to the third surface and opposing to the second surface of the light emitting element, and
the side surface of the light emitting element and the side surface of the wavelength conversion layer form inclined surfaces that respectively cause a distance to the adjacent light emitting element and a distance to the adjacent wavelength conversion layer to narrow from the second surface side of the light emitting element toward the third surface side of the wavelength conversion layer.
   (3)

The light emitting device according to (1) or (2), in which the reflection film is collectively formed via an insulation film provided to extend from the second surface of the light emitting element to the side surface of the light emitting element and to the side surface of the wavelength conversion layer.

(4)

The light emitting device according to any one of (1) to (3), in which the light emitting element includes a first conductive-type layer, an active layer, and a second conductive-type layer having a different conductive type from the first conductive-type layer, stacked from the second surface side, and also includes a first electrode that applies voltage to the first conductive-type layer and a second electrode that applies voltage to the second conductive-type layer, provided on the second surface side.

(5)

The light emitting device according to (4), in which the light emitting element further includes a first contact layer provided on a surface opposite to the active layer side of the first conductive-type layer, and
the first electrode is electrically coupled to the first conductive-type layer via the first contact layer.
   (6)

The light emitting device according to (4) or (5), in which the light emitting element further includes a recess from which the second conductive-type layer is exposed on the second surface side, and
the second electrode is electrically coupled, at the recess, to the second conductive-type layer from the second surface side.
   (7)

The light emitting device according to any one of (4) to (6), in which the reflection film is in contact with a side surface of the second conductive-type layer, and
the second electrode is electrically coupled to the second conductive-type layer via the reflection film.
   (8)

The light emitting device according to any one of (4) to (7), in which the light emitting element further includes a second contact layer that is provided on a surface opposite to the active layer side of the second conductive-type layer and is in contact with the reflection film, and
the second electrode is electrically coupled to the second conductive-type layer via the reflection film and the second contact layer.
   (9)

The light emitting device according to any one of (1) to (8), in which a plurality of the light emitting elements is arranged in an array, and
the reflection film is continuously provided across the plurality of light emitting elements.
   (10)

The light emitting device according to any one of (1) to (9), in which the reflection film includes a metal material.

(11)

The light emitting device according any one of (1) to (9), in which the reflection film includes a dielectric multilayer film.

(12)

The light emitting device according to any one of (1) to (11), in which the light emitting element includes a GaN-based semiconductor material.

(13)

The light emitting device according to any one of (1) to (12), in which the side surface of the light emitting element and the side surface of the wavelength conversion layer form substantially a same surface.

(14)

A method for manufacturing a light emitting device, the method including:
forming a separation groove that separates a GaN-based semiconductor layer provided on one surface of a silicon substrate and including a second conductive-type layer, an active layer, and a first conductive-type layer having a different conductive type from the second conductive-type layer stacked in this order, as a plurality of light emitting elements, from the first conductive-type layer side to a part of the silicon substrate;
forming a reflection film continuously provided from surfaces of the plurality of light emitting elements, to a side surface and a bottom surface of the separation groove; and
peeling off the silicon substrate from a surface opposite to the one surface, to form a plurality of openings sectioned by the separation groove for the respective plurality of light emitting elements, and thereafter forming a wavelength conversion layer in each of the plurality of openings.
   (15)

The method for manufacturing the light emitting device according to (14), in which, after forming the separation groove, the reflection film is formed after forming a first insulation film continuously provided from the surfaces of the plurality of light emitting elements to the side surface and the bottom surface of the separation groove.

(16)

The method for manufacturing the light emitting device according to (14) or (15), in which, after forming the reflection film, the separation groove is filled by forming a second insulation film.

(17)

The method for manufacturing the light emitting device according to (16), in which, after forming the second insulation film, a first electrode that applies voltage to the first conductive-type layer and a second electrode that applies voltage to the second conductive-type layer are formed.

(18)

An image display apparatus provided with a light emitting device,
the light emitting device including:
a light emitting element having a first surface as a light emitting surface and a second surface opposite to the first surface;
a wavelength conversion layer that is provided on the first surface side and converts wavelength of emitted light emitted from the light emitting element; and
a reflection film collectively formed from at least a part of the second surface of the light emitting element, to a side surface of the light emitting element and to a side surface of the wavelength conversion layer.

This application claims priority based on Japanese Patent Application No. 2022-039651 filed on Mar. 14, 2022 with Japan Patent Office, the entire contents of which are incorporated in this application by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A light emitting device, comprising:
a light emitting element having a first surface as a light emitting surface and a second surface opposite to the first surface;
a wavelength conversion layer that is provided on the first surface side and converts wavelength of emitted light emitted from the light emitting element; and
a reflection film collectively formed from at least a part of the second surface of the light emitting element, to a side surface of the light emitting element and to a side surface of the wavelength conversion layer.

2. The light emitting device according to claim 1, wherein the wavelength conversion layer has a third surface from which the emitted light after wavelength conversion is extracted, and a fourth surface opposite to the third surface and opposing to the second surface of the light emitting element, and
the side surface of the light emitting element and the side surface of the wavelength conversion layer form inclined surfaces that respectively cause a distance to the adjacent light emitting element and a distance to the adjacent wavelength conversion layer to narrow from the second surface side of the light emitting element toward the third surface side of the wavelength conversion layer.

3. The light emitting device according to claim 1, wherein the reflection film is collectively formed via an insulation film provided to extend from the second surface of the light emitting element to the side surface of the light emitting element and to the side surface of the wavelength conversion layer.

4. The light emitting device according to claim 1, wherein the light emitting element includes a first conductive-type layer, an active layer, and a second conductive-type layer having a different conductive type from the first conductive-type layer, stacked from the second surface side, and also includes a first electrode that applies voltage to the first conductive-type layer and a second electrode that applies voltage to the second conductive-type layer, provided on the second surface side.

5. The light emitting device according to claim 4, wherein the light emitting element further includes a first contact layer provided on a surface opposite to the active layer side of the first conductive-type layer, and
the first electrode is electrically coupled to the first conductive-type layer via the first contact layer.

6. The light emitting device according to claim 4, wherein the light emitting element further includes a recess from which the second conductive-type layer is exposed on the second surface side, and
the second electrode is electrically coupled, at the recess, to the second conductive-type layer from the second surface side.

7. The light emitting device according to claim 4, wherein the reflection film is in contact with a side surface of the second conductive-type layer, and
the second electrode is electrically coupled to the second conductive-type layer via the reflection film.

8. The light emitting device according to claim 4, wherein the light emitting element further includes a second contact layer that is provided on a surface opposite to the active layer side of the second conductive-type layer and is in contact with the reflection film, and
the second electrode is electrically coupled to the second conductive-type layer via the reflection film and the second contact layer.

9. The light emitting device according to claim 1, wherein a plurality of the light emitting elements is arranged in an array, and
the reflection film is continuously provided across the plurality of light emitting elements.

10. The light emitting device according to claim 1, wherein the reflection film includes a metal material.

11. The light emitting device according to claim 1, wherein the reflection film includes a dielectric multilayer film.

12. The light emitting device according to claim 1, wherein the light emitting element includes a GaN-based semiconductor material.

13. The light emitting device according to claim 1, wherein the side surface of the light emitting element and the side surface of the wavelength conversion layer form substantially a same surface.

14. A method for manufacturing a light emitting device, the method comprising:
forming a separation groove that separates a GaN-based semiconductor layer provided on one surface of a silicon substrate and including a second conductive-type layer, an active layer, and a first conductive-type layer having a different conductive type from the second conductive-type layer stacked in this order, as a plurality of light emitting elements, from the first conductive-type layer side to a part of the silicon substrate;
forming a reflection film continuously provided from surfaces of the plurality of light emitting elements, to a side surface and a bottom surface of the separation groove; and
peeling off the silicon substrate from a surface opposite to the one surface, to form a plurality of openings sectioned by the separation groove for the respective plurality of light emitting elements, and thereafter forming a wavelength conversion layer in each of the plurality of openings.

15. The method for manufacturing the light emitting device according to claim 14, wherein, after forming the separation groove, the reflection film is formed after forming a first insulation film continuously provided from the surfaces of the plurality of light emitting elements to the side surface and the bottom surface of the separation groove.

16. The method for manufacturing the light emitting device according to claim 14, wherein, after forming the reflection film, the separation groove is filled by forming a second insulation film.

17. The method for manufacturing the light emitting device according to claim 16, wherein, after forming the second insulation film, a first electrode that applies voltage to the first conductive-type layer and a second electrode that applies voltage to the second conductive-type layer are formed.

18. An image display apparatus provided with a light emitting device,
the light emitting device comprising:
a light emitting element having a first surface as a light emitting surface and a second surface opposite to the first surface;
a wavelength conversion layer that is provided on the first surface side and converts wavelength of emitted light emitted from the light emitting element; and
a reflection film collectively formed from at least a part of the second surface of the light emitting element, to a side surface of the light emitting element and to a side surface of the wavelength conversion layer.
